(19) United States
(12) Patent Application Publication
(10) Pub. No.: US 2024/0222349 A1
(43) Pub. Date: Jul. 4, 2024

(54) POWER MODULE

(71) Applicant: Mitsubishi Electric Corporation, Tokyo (JP)

(72) Inventor: Kenta NAKAHARA, Tokyo (JP)

(73) Assignee: Mitsubishi Electric Corporation, Tokyo (JP)

(21) Appl. No.: 18/556,265

(22) PCT Filed: Jul. 1, 2021
(86) PCT No.: PCT/JP2021/024915

§ 371 Date: Oct. 19, 2023

(51) Int. Cl. H01L 25/18; H01L 23/00; H01L 23/367; H01L 25/065

(52) U.S. Cl. CPC H01L 25/18; H01L 23/3675; H01L 24/32; H01L 24/45; H01L 24/48; H01L 24/73; H01L 24/83; H01L 24/85; H01L 25/0655; H01L 2224/32225; H01L 2224/32245; H01L 2224/45014; H01L 2224/45147; H01L 2224/4807; H01L 2224/48096; H01L 2224/48245; H01L 2224/73215; H01L 2224/73265; H01L 2224/8321; H01L 2224/83815; H01L 2224/85815; H01L 2924/30101; H01L 2924/351

(57) ABSTRACT

The present disclosure relates to a power module including a plurality of semiconductor elements through which a main current flows in a thickness direction; a substrate on which the plurality of semiconductor elements are mounted; a base plate on which the substrate is mounted; a case that is bonded to the base plate and houses the plurality of semiconductor elements; a plurality of main wiring boards incorporated in an upper portion of the case on a side opposite to the base plate and arranged in parallel to the base plate; and a plurality of wires bonded to lower surfaces of the plurality of main wiring boards that face the plurality of semiconductor elements, in which an upper surface electrode of each of the plurality of semiconductor elements is electrically connected to a corresponding one of the plurality of main wiring boards with the plurality of wires and a bonding material.

### TECHNICAL FIELD

The present disclosure relates to a power module, and particularly to a power module having an improved wiring structure.

### BACKGROUND ART

Patent Document 1 discloses a power module capable of improving reliability by securing stable bonding strength. FIG. 1 of Patent Document 1 illustrates a power module including a heat dissipation metal base plate, an insulating substrate, a power semiconductor element, a surface electrode, a main terminal, an opening, a bonding ribbon, a case, and a sealing resin.

In the power module, the insulating substrate is bonded onto the heat dissipation metal base plate with solder or the like. The insulating substrate includes an insulating layer and a metal plate. The main terminal is a plate-shaped electrode made of copper, and has an opening at a position facing the power semiconductor element. The bonding ribbon is formed in a loop shape across the opening formed in the main terminal, and both ends thereof are ultrasonically welded to the main terminal. A loop portion of the bonding ribbon is ultrasonically welded to the surface electrode of the power semiconductor element.

### PRIOR ART DOCUMENT

### Patent Document

Patent Document 1: International Publication No. 2015/079600

### SUMMARY

### Problem to be Solved by the Invention

In Patent Document 1, the main terminal and the surface electrode of the power semiconductor element are connected with the bonding ribbon by ultrasonic welding. In order to perform ultrasonic welding, it is necessary to insert an instrument for bonding from an upper surface of the case, and thus it is necessary to provide an opening, and it is therefore difficult to reduce the size. In addition, since the bonding ribbon is ultrasonically welded to the surface electrode of the semiconductor element, a degree of freedom of a size of the semiconductor element and a size of the electrode bonded to the semiconductor element is small, and there is a problem that it is not possible to flexibly cope with a change in the size of the semiconductor element.

The present disclosure has been made to solve the above problems, and an object of the present disclosure is to provide a power module that can be reduced in size, can flexibly cope with a change in size of a semiconductor element, and can improve productivity.

### Means to Solve the Problem

A power module according to the present disclosure includes a plurality of semiconductor elements through which a main current flows in a thickness direction; a substrate on which the plurality of semiconductor elements are mounted; a base plate on which the substrate is mounted; a case that is bonded to the base plate and houses the plurality of semiconductor elements; a plurality of main wiring boards incorporated in an upper portion of the case on a side opposite to the base plate and arranged in parallel to the base plate; and a plurality of wires bonded to lower surfaces of the plurality of main wiring boards that face the plurality of semiconductor elements, in which an upper surface electrode of each of the plurality of semiconductor elements is electrically connected to a corresponding one of the plurality of main wiring boards with the plurality of wires and a bonding material.

### Effects of the Invention

According to the power module according to the present disclosure, it is possible to obtain a power module that can be reduced in size, can flexibly cope with a change in size of a semiconductor element, and can improve productivity.

### BRIEF DESCRIPTION OF DRAWINGS

FIG. 1 is a plan view illustrating a configuration of a power module according to First Embodiment.

FIG. 2 is a cross-sectional view illustrating the configuration of the power module according to First Embodiment.

FIG. 3 is a diagram illustrating a circuit configuration of the power module according to First Embodiment.

FIG. 4 is a cross-sectional view for explaining a first example of a method of assembling the power module according to First Embodiment.

FIG. 5 is a cross-sectional view for explaining the first example of the method of assembling the power module according to First Embodiment.

FIG. 6 is a cross-sectional view for explaining a second example of the method of assembling the power module according to First Embodiment.

FIG. 7 is a cross-sectional view for explaining the second example of the method of assembling the power module according to First Embodiment.

FIG. 8 is a cross-sectional view for explaining a third example of the method of assembling the power module according to First Embodiment.

FIG. 9 is a cross-sectional view for explaining the third example of the method of assembling the power module according to First Embodiment.

FIG. 10 is a plan view illustrating a configuration of a power module according to Second Embodiment.

FIG. 11 is a cross-sectional view illustrating the configuration of the power module according to Second Embodiment.

FIG. 12 is a plan view illustrating a configuration of a power module according to Third Embodiment.

FIG. 13 is a cross-sectional view illustrating the configuration of the power module according to Third Embodiment.

FIG. 14 is a diagram for explaining suppression of occurrence of an oscillation phenomenon in the power module according to Third Embodiment.

FIG. 15 is a diagram for explaining suppression of occurrence of an oscillation phenomenon in the power module according to Third Embodiment.

### DESCRIPTION OF EMBODIMENTS

### Introduction

The drawings are schematically illustrated, and mutual relationships between sizes and positions of images illustrated in different drawings are not necessarily accurate, and can be appropriately changed. In addition, in the following description, similar constituent elements are given identical reference signs, and names and functions thereof are also similar. Therefore, detailed description thereof may be omitted.

In addition, in the present specification, the terms “on” and “covering” do not exclude a case where something is present between constituent elements. For example, an expression “B provided on A” or “A covers B” can mean not only a case where another constituent element C is not provided between A and B, but also a case where another constituent element C is provided between A and B.

In addition, in the following description, terms meaning specific positions and directions such as “upper”, “lower”, “side”, “bottom”, “front”, and “back” may be used, but these terms are used for convenience to facilitate understanding of the contents of the embodiment, and is not related to directions during actual implementation.

### First Embodiment

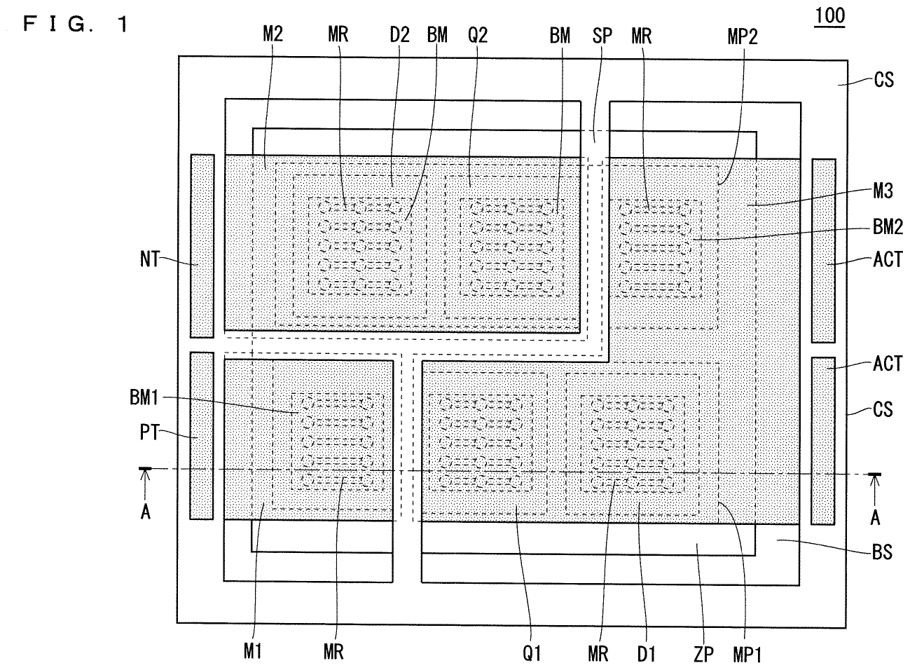

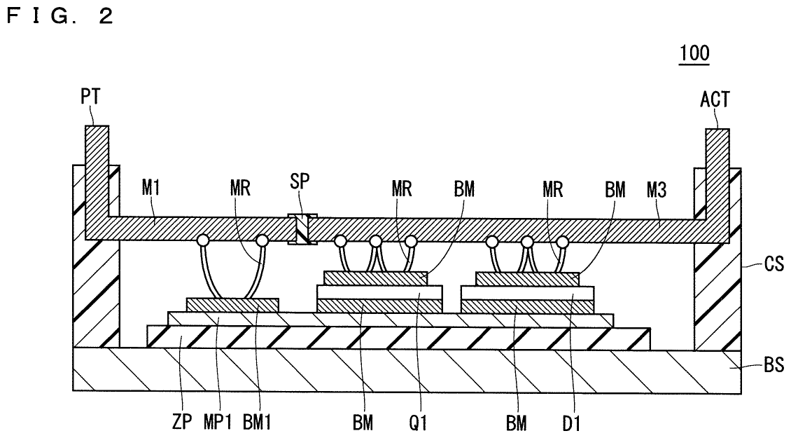

FIG. 1 is a plan view illustrating a configuration of a power module 100 according to First Embodiment, and is a top view of the power module 100 as viewed from above. FIG. 2 is a cross-sectional view taken along line A-A of arrow directions in FIG. 1.

As illustrated in FIG. 2, the power module 100 is, for example, configured such that an insulating substrate ZP is bonded to an upper surface of a base plate BS that is formed of a metal plate such as a copper plate and functions as a heat sink with a bonding material such as solder (not illustrated). The base plate BS is disposed so as to cover an opening on a bottom surface side of a frame-shaped resin case CS having an opening on an upper surface side and a bottom surface side, and the base plate BS constitutes a bottom surface of the case CS. A heat dissipation mechanism such as a cooling fin can be attached to a lower surface of the base plate BS.

The insulating substrate ZP is mainly formed of a ceramic substrate such as silicon nitride, alumina, or aluminum nitride, and conductor patterns MP1 and MP2 are formed on an upper surface of the ceramic substrate as illustrated in FIG. 1. On the conductor pattern MP1 of the insulating substrate ZP, a transistor Q1 and a diode D1 as semiconductor elements are bonded with a bonding material BM such as solder. On the conductor pattern MP2, a transistor Q2 and a diode D2 are bonded with the bonding material BM. Independent bonding materials BM1 and BM2 are provided on the conductor patterns MP1 and MP2, respectively so as to form a column with the semiconductor elements.

The type of the transistors Q1 and Q2 is not particularly limited, and a metal oxide semiconductor field effect transistor (MOSFET), an insulated gate bipolar transistor (IGBT), or the like can be used. The type of the diodes D1 and D2 is not particularly limited, and a Schottky barrier diode (SBD), a PN junction diode, or the like can be used.

Furthermore, as illustrated in FIG. 2, on an upper surface side of the case CS, a main wiring board M3, which is a third main wiring board, is provided so as to cover an upper side of the transistor Q1 and the diode D1, and a main wiring board M1, which is a first main wiring board, is provided so as to cover an upper side of the independent bonding material BM1. One ends of the main wiring boards M3 and M1 protrude perpendicularly from an upper end of the case CS as an output terminal ACT and a P-side terminal PT, respectively, and the other ends of the main wiring boards M3 and M1 are embedded in a wiring support portion SP provided integrally with the case CS.

Furthermore, as illustrated in FIG. 1, a main wiring board M2, which is a second main wiring board, is provided on an upper surface side of the case CS so as to cover an upper side of the transistor Q2 and the diode D2. One end of the main wiring board M2 protrudes perpendicularly from the upper end of the case CS as an N-side terminal NT, and the other end of the main wiring board M2 is embedded in the wiring support portion SP. Furthermore, the main wiring board M3 has an L shape in plan view, covers the upper side of the transistor Q1 and the diode D1, and covers an upper side of the independent bonding material BM2 provided on the conductor pattern MP2.

Here, although two output terminals ACT are provided, they are connected inside the case CS. This is to increase a current capacity since an amount of current flowing through the output terminal ACT is larger than that flowing through the P-side terminal PT and the N-side terminal NT during actual operation.

As illustrated in FIG. 1, the wiring support portion SP is provided along an outline of each wiring in a portion where the main wiring board M1 and the main wiring board M2 are adjacent to each other, a portion where the main wiring board M1 and the main wiring board M3 are adjacent to each other, and a portion where the main wiring board M2 and the main wiring board M3 are adjacent to each other, and supports each wiring board so that each wiring is not supported at only one end.

Furthermore, as illustrated in FIG. 2, a plurality of wires MR made of metal wires or metal ribbons are bonded to a lower surface of the main wiring board M3 that faces the transistor Q1 and the diode D1. A method of bonding the wires MR and the main wiring board M3 is not particularly limited, and wire bonding, ultrasonic bonding, or the like can be used. Both ends of the wires MR are bonded to the main wiring board M3 so as to have a loop shape protruding from the lower surface of the main wiring board M3, and a tip of the loop is bonded to the bonding material BM provided on upper surface electrodes of the transistor Q1 and the diode D1. Therefore, the upper surface electrodes of the transistor Q1 and the diode D1 are electrically connected to the main wiring board M3.

Furthermore, as illustrated in FIG. 2, the wire MR is also bonded to a lower surface of the main wiring board M1 that faces the independent bonding material BM1. Both ends of the wire MR are bonded to the main wiring board M1 so as to have a loop shape protruding from the lower surface of the main wiring board M1, and a tip of the loop is bonded to the independent bonding material BM1. The main wiring board M3 and the main wiring board M1 are electrically insulated by the wiring support portion SP, and the main wiring board M1 is electrically connected to lower surface electrodes of the transistor Q1 and the diode D1.

By forming the wires MR in a loop shape, a change in size of a semiconductor element to be mounted can be flexibly coped with by adjusting arrangement and heights of the wires MR, and therefore productivity can be improved.

Similarly, the main wiring board M2 and upper electrodes of the transistor Q2 and the diode D2 are also electrically connected by the wires MR and the bonding material BM, and the main wiring board M3 and the independent bonding material BM2 are also electrically connected to each other by the wire MR. The independent bonding material BM2 electrically connects lower surface electrodes of the transistor Q2 and the diode D2 to the main wiring board M3.

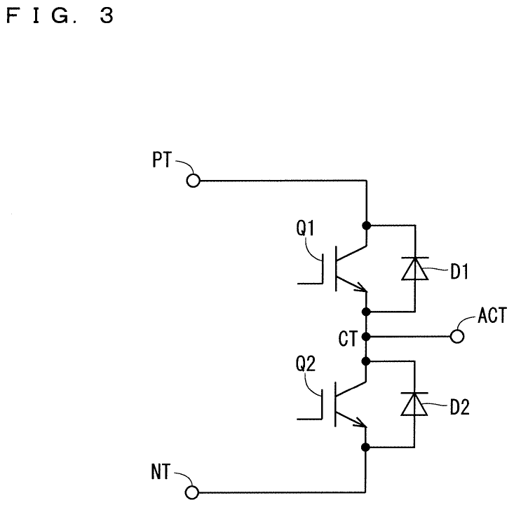

The power module 100 having the above-described configuration constitutes a circuit as illustrated in FIG. 3. As illustrated in FIG. 3, in the power module 100, the N-channel transistors Q1 and Q2 are connected in series between the P-side terminal PT serving as a main power supply terminal of a high potential which is a first potential and the N-side terminal NT serving as a main power supply terminal of a low potential which is a second potential, and a connection node CT of both transistors is connected to the output terminal ACT. This constitutes a single-phase inverter circuit. Note that in FIG. 3, the transistors Q1 and Q2 are illustrated as IGBTs.

The diodes D1 and D2 are connected in anti-parallel to the transistors Q1 and Q2, respectively, and function as freewheel diodes. Note that each of the transistors is a transistor having a vertical structure in which a main current flows in a thickness direction, and each of the diodes is also a diode having a vertical structure in which a main current flows in a thickness direction.

Note that although control signals are given from a control circuit to gates of the transistors Q1 and Q2, illustration thereof is omitted. Although illustration of the control circuit is also omitted in FIGS. 1 and 2, for example, a gate pad is provided on the upper electrode side of the transistors Q1 and Q2, and the transistors Q1 and Q2 can be connected to the control circuit by the gate pas and a bonding wire. A feature of the present disclosure lies in a connection structure between main electrodes of a transistor and a diode and a main wiring board, and a conventional configuration is adopted as for connection between a gate of the transistor and a control circuit, and therefore illustration thereof is omitted for convenience.

By using copper (Cu) or a copper alloy as a material of the main wiring boards M1 to M3 and the wires MR, electric resistance of a current path of the power module 100 can be reduced, and the life of the power module 100 can be improved by keeping heat generation during energization small. In addition, copper also has an advantage of being easily bonded to a bonding material. Alternatively, aluminum (Al) can also be used.

A reason why the wires MR are bonded to the transistors and the diodes by using a bonding material such as solder is also related to metallization of an upper electrode of the semiconductor element. In order to connect a copper wire to an upper electrode of a semiconductor element by wire bonding in a conventional wiring technique, the upper electrode needs to be metallized with a hard metal such as copper. However, metallization with copper makes material management difficult, but by using a bonding material for connection between the upper surface electrode of the semiconductor element and the wires MR, it becomes possible to perform bonding even in a case where nickel (Ni) plating is applied to the upper surface electrode or Ni plating is applied onto gold (Au) plating, and material management becomes easy.

Furthermore, a main reason why the wires MR are bonded to the transistors and the diodes by using a bonding material such as solder is to melt the bonding material by reflow or heating using a hot plate and to bond the bonding material to the wires MR.

By adopting such a configuration, the power module 100 can improve assemblability as compared with a case where an upper surface electrode of a chip-shaped semiconductor element and a main wiring board are connected by ultrasonic welding. Furthermore, since it is not necessary to insert an instrument for bonding from an upper surface of a case, it is not necessary to provide an opening, and it is easy to reduce the size of the power module 100. Furthermore, even a change in the size of the semiconductor element to be mounted can be flexibly coped with by adjusting arrangement and heights of the wires MR, and productivity can be improved.

### <Assembling Method>

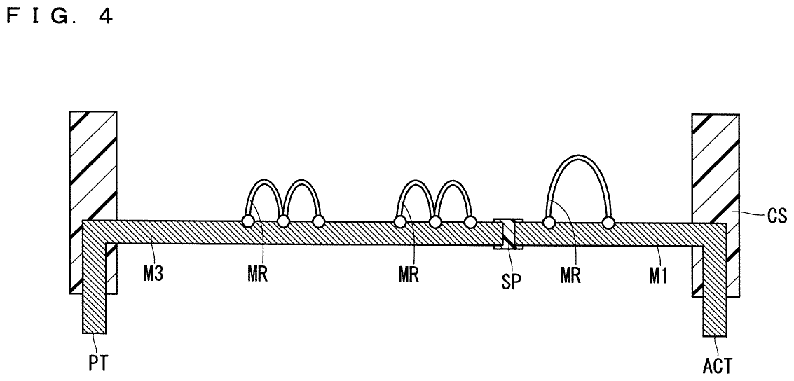

Hereinafter, a method of assembling the power module 100 will be described with reference to FIGS. 4 to 9.

### First Example

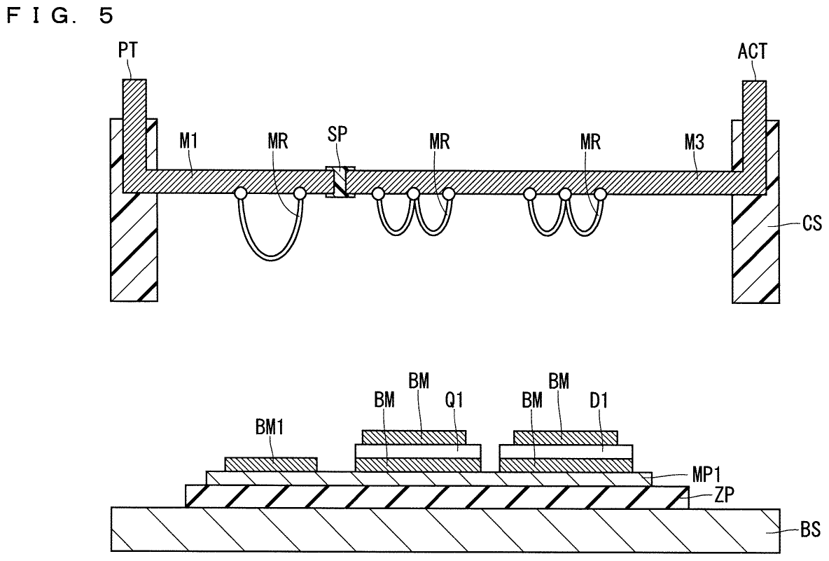

A first example of the assembling method will be described with reference to FIGS. 4 and 5. First, the case CS in which the main wiring boards M1 to M3 are incorporated is prepared. That is, when the case CS is molded with resin, the main wiring boards M1 to M3 are embedded in the case CS by insert molding. The insert molding is a method of incorporating a metal member such as an electrode into a resin member by injection molding using a molding machine, and can embed the main wiring boards M1 to M3 in the case CS by mounting press members such as the main wiring boards M1 to M3 on a lower mold by using a mold divided into an upper mold and the lower mold, aligning the lower mold with the upper mold, injecting a molten resin into the mold, and cooling the resin. Note that the wiring support portion SP is also formed at the time of molding the case CS.

The prepared case CS is disposed so that a side where the wires MR are to be provided becomes an upper side, and the wires MR are bonded to predetermined positions of the main wiring boards M1 to M3, that is, positions facing the transistor Q1, the diode D1, and the independent bonding material BM1 and positions facing the transistor Q2, the diode D2, and the independent bonding material BM2 as illustrated in FIG. 4. Wire bonding, ultrasonic bonding, or the like is used as the bonding. At this time, both ends of the wires MR are bonded to the main wiring boards M1 to M3, a loop is formed between both ends, and the height from the main wiring board to a tip of the loop is set at each position so that the tip of the loop reaches the bonding materials BM on the upper surface electrodes of the transistors Q1 and Q2 and the diodes D1 and D2 and the independent bonding materials BM1 and BM2 when the case CS is put on the base plate BS.

Next, as illustrated in FIG. 5, the case CS is placed from an upper side of the base plate BS on which the transistors Q1 and Q2, the diodes D1 and D2, and the independent bonding materials BM1 and BM2 are mounted, and the base plate BS and the case CS are bonded. A method of bonding is not limited, and the bonding can be performed by using, for example, an adhesive.

Thereafter, the base plate BS is put into, for example, a reflow furnace, the bonding materials BM, the independent bonding materials BM1 and BM2 are melted by solder reflow, and the wires MR are bonded to the bonding materials BM and the independent bonding materials BM1 and BM2, and thereby the configuration illustrated in FIGS. 1 and 2 is obtained. Thereafter, a molding resin is introduced into the case CS, and the transistors Q1 and Q2, the diodes D1 and D2, and the wires MR are resin-sealed, but illustration thereof is omitted for convenience.

### Second Example

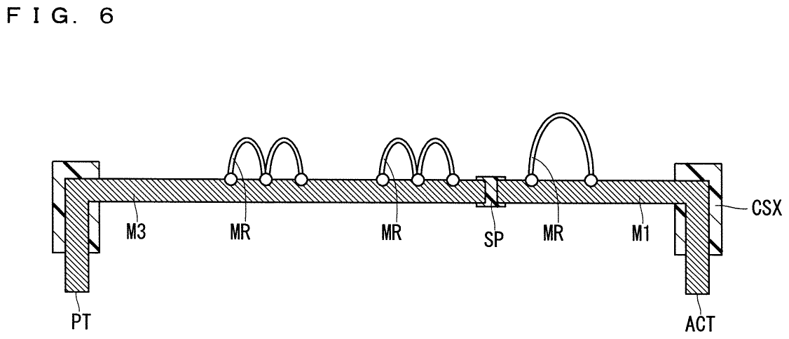

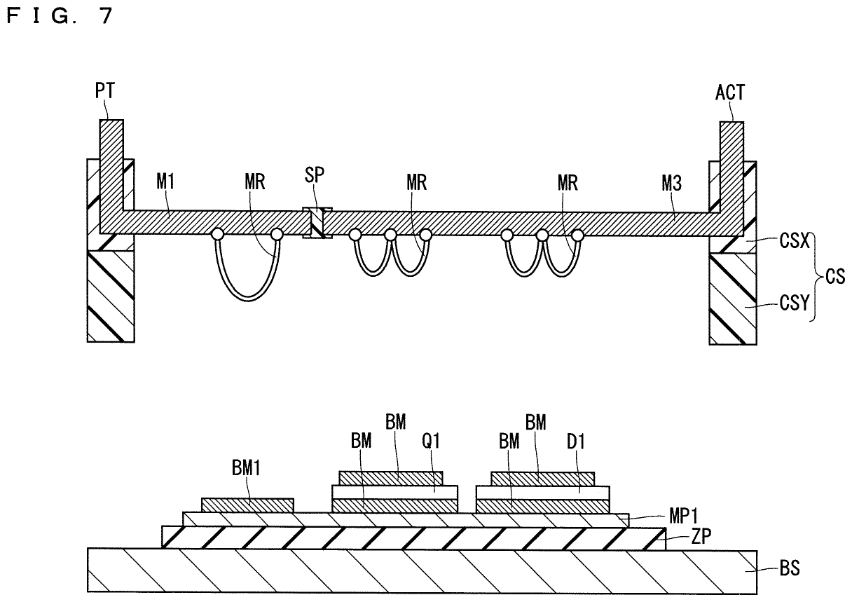

A second example of the assembling method will be described with reference to FIGS. 6 and 7. First, A case upper portion CSX in which the main wiring boards M1 to M3 are incorporated is prepared. As illustrated in FIG. 6, the case upper portion CSX is a member in which the main wiring boards M1 to M3 are embedded by insert molding, and has a configuration corresponding to an upper portion of the case CS illustrated in FIG. 2.

The prepared case upper portion CSX is disposed so that a side where the wires MR are to be provided becomes an upper side, and the wires MR are bonded to predetermined positions of the main wiring boards M1 to M3, that is, positions facing the transistor Q1, the diode D1, and the independent bonding material BM1 and positions facing the transistor Q2, the diode D2, and the independent bonding material BM2 as illustrated in FIG. 6. A method of bonding the wires MR is the same as the method described with reference to FIG. 4.

Next, as illustrated in FIG. 7, a case lower portion CSY is bonded to the case upper portion CSX to complete the case CS. A method of bonding is not limited, and the bonding can be performed by using, for example, an adhesive.

Then, the case CS is placed from an upper side of the base plate BS on which the transistors Q1 and Q2, the diodes D1 and D2, and the independent bonding materials BM1 and BM2 are mounted, and the base plate BS and the case CS are bonded.

Thereafter, the base plate BS is put into, for example, a reflow furnace, the bonding materials BM, the independent bonding materials BM1 and BM2 are melted by solder reflow, and the wires MR are bonded to the bonding materials BM and the independent bonding materials BM1 and BM2, and thereby the configuration illustrated in FIGS. 1 and 2 is obtained.

### Third Example

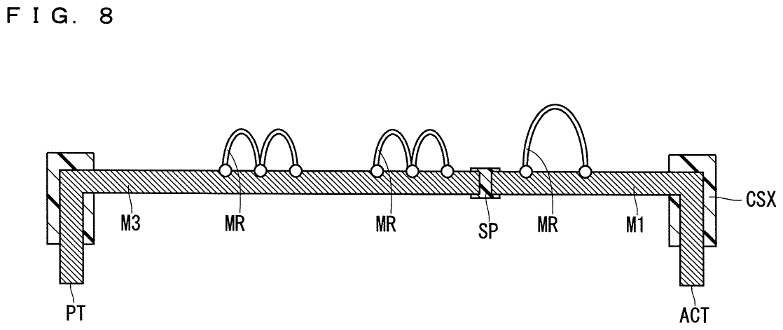

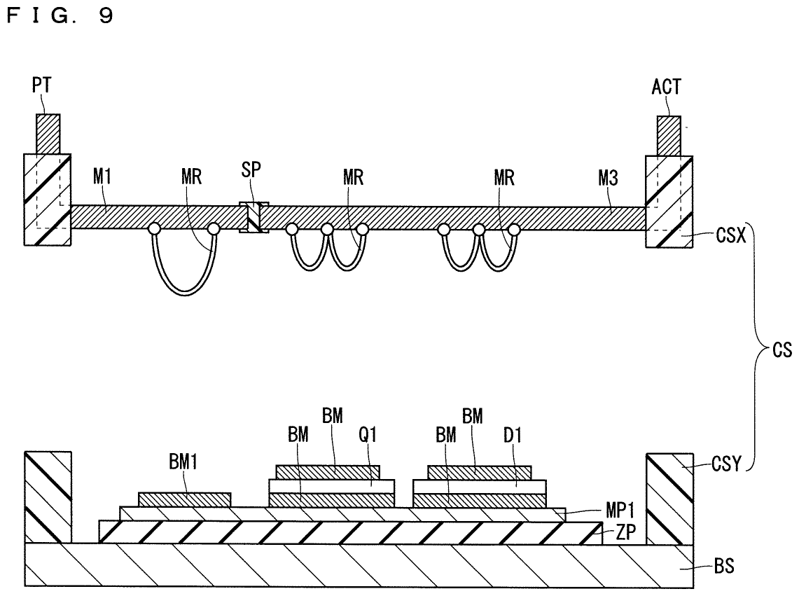

A second example of the assembling method will be described with reference to FIGS. 8 and 9. As illustrated in FIG. 8, the third example is the same as the second example in that the case upper portion CSX in which the main wiring boards M1 to M3 are incorporated is prepared, the prepared case upper portion CSX is disposed so that a side where the wires MR are to be provided becomes an upper side, and the wires MR are bonded.

Next, as illustrated in FIG. 9, the case upper portion CSX is placed from an upper side of the base plate BS on which the transistors Q1 and Q2, the diodes D1 and D2, and the independent bonding materials BM1 and BM2 are mounted and to which the case lower portion CSY has been bonded, and the case lower portion CSY and the case upper portion CSX are bonded.

Thereafter, the base plate BS is put into, for example, a reflow furnace, the bonding materials BM, the independent bonding materials BM1 and BM2 are melted by solder reflow, and the wires MR are bonded to the bonding materials BM and the independent bonding materials BM1 and BM2, and thereby the configuration illustrated in FIGS. 1 and 2 is obtained.

In a case where the case upper portion CSX and the case lower portion CSY are separated as in the second example and the third example described above, the case lower portion CSY can be formed as a common member, and the case upper portion CSX can be changed in accordance with the product specification of the power module, and therefore flexible response is possible. Furthermore, by forming the case upper portion CSX as a separate member, a target of insert molding is made small, yield of the insert molding is improved, and as a result, it is possible to reduce loss caused by a defect of a member and to reduce a member cost.

### Second Embodiment

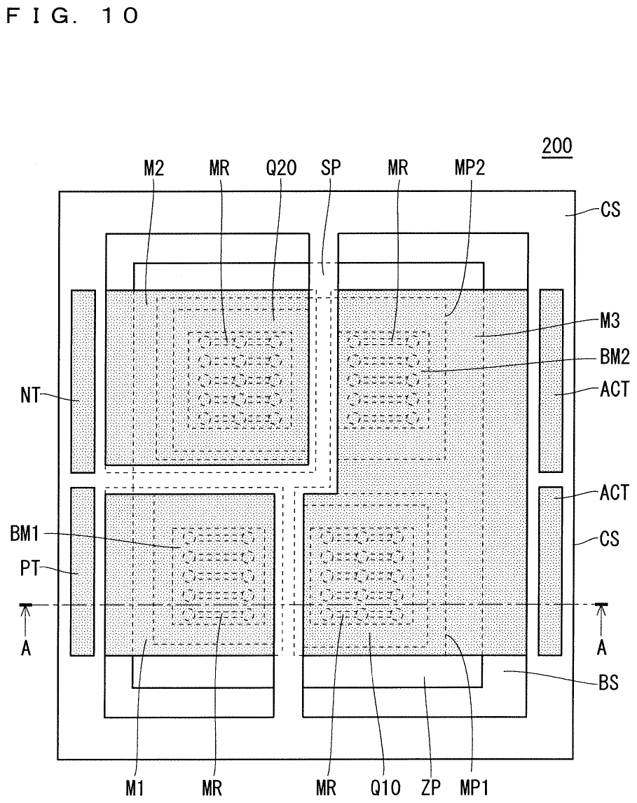

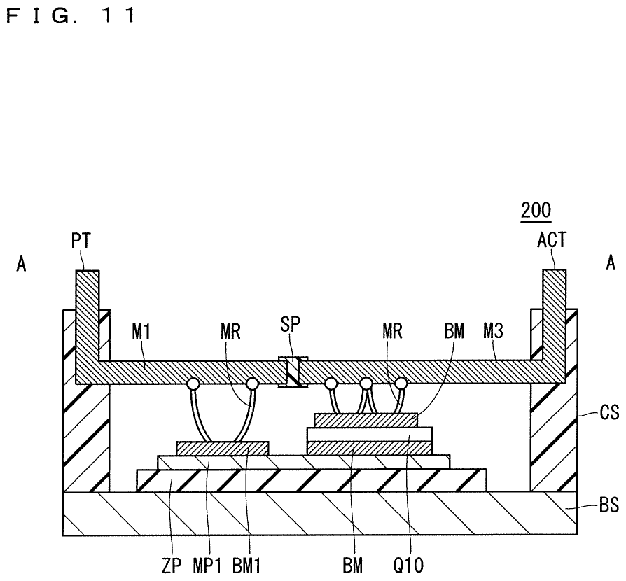

FIG. 10 is a plan view illustrating a configuration of a power module 200 according to Second Embodiment, and is a top view of the power module 200 as viewed from above. FIG. 11 is a cross-sectional view taken along line A-A of arrow directions in FIG. 10. Note that in FIGS. 10 and 11, identical elements to those of the power module 100 described with reference to FIGS. 1 and 2 are given identical reference signs, and repeated description is omitted.

As illustrated in FIG. 10, a transistor Q10 (first switching element) as a semiconductor element is bonded onto a conductor pattern MP1 of an insulating substrate ZP with a bonding material BM such as solder. Furthermore, a transistor Q20 (second switching element) is bonded onto a conductor pattern MP2 with the bonding material BM. Independent bonding materials BM1 and BM2 are provided on the conductor patterns MP1 and MP2, respectively so as to form a column with the semiconductor elements.

As the transistors Q10 and Q20, a reverse-conducting IGBT (RC-IGBT) that includes a free wheeling diode and achieves characteristics of the IGBT and the free wheeling diode in one structure is used. Since the free wheeling diode is included, a semiconductor element to be mounted on a conductor pattern can be a transistor only, and therefore a mounting area of the semiconductor element can be reduced, and the size of the power module can be further reduced. Note that, in a case where the mounting area of the semiconductor element is not changed, the number of semiconductor elements to be mounted can be increased, and in this case, a current density of the power module can be increased.

Note that, instead of using the RC-IGBT, a MOSFET including a Schottky barrier diode can also be used as the reverse-conducting transistor, and even in this case, it is possible to further reduce the size of the power module and increase the current density.

As illustrated in FIG. 11, on an upper surface side of a case CS, a main wiring board M3 is provided so as to cover an upper side of the transistor Q10, and a main wiring board M1 is provided so as to cover an upper side of the independent bonding material BM1. One ends of the main wiring boards M3 and M1 protrude perpendicularly from an upper end of the case CS as an output terminal ACT and a P-side terminal PT, respectively, and the other ends of the main wiring boards M3 and M1 are embedded in a wiring support portion SP provided integrally with the case CS.

Furthermore, as illustrated in FIG. 10, a main wiring board M2 is provided on an upper surface side of the case CS so as to cover an upper side of the transistor Q20. One end of the main wiring board M2 protrudes perpendicularly from the upper end of the case CS as an N-side terminal NT, and the other end of the main wiring board M2 is embedded in the wiring support portion SP. Furthermore, the main wiring board M3 covers the upper side of the transistor Q10, and covers an upper side of the independent bonding material BM2 provided on the conductor pattern MP2.

As illustrated in FIG. 10, the wiring support portion SP is provided along an outline of each wiring in a portion where the main wiring board M1 and the main wiring board M2 are adjacent to each other, a portion where the main wiring board M1 and the main wiring board M3 are adjacent to each other, and a portion where the main wiring board M2 and the main wiring board M3 are adjacent to each other, and supports each wiring so that each wiring is not supported at only one end.

Furthermore, as illustrated in FIG. 11, a plurality of wires MR made of metal wires or metal ribbons are bonded to a lower surface of the main wiring board M3 that faces the transistor Q10. Both ends of the wires MR are bonded to the main wiring board M3 so as to have a loop shape protruding from the lower surface of the main wiring board M3, and a tip of the loop is bonded to the bonding material BM provided on an upper surface electrode of the transistor Q10. Therefore, the upper surface electrode of the transistor Q10 is electrically connected to the main wiring board M3.

Furthermore, as illustrated in FIG. 11, the wire MR is also bonded to a lower surface of the main wiring board M1 that faces the independent bonding material BM1. Both ends of the wire MR are bonded to the main wiring board M3 so as to have a loop shape protruding from the lower surface of the main wiring board M1, and a tip of the loop is bonded to the independent bonding material BM1. The main wiring board M3 and the main wiring board M1 are electrically insulated by the wiring support portion SP, and the main wiring board M1 is electrically connected to a lower surface electrode of the transistor Q10.

Similarly, the main wiring board M2 and an upper electrode of the transistor Q20 are also electrically connected by the wires MR and the bonding material BM, and the main wiring board M3 and the independent bonding material BM2 are also electrically connected to each other by the wire MR. The independent bonding material BM2 electrically connects a lower surface electrode of the transistor Q20 to the main wiring board M3.

The power module 200 having the configuration described above constitutes a single-phase inverter circuit similarly to the power module 100 of First Embodiment. The circuit configuration is similar to that of the power module 100 illustrated in FIG. 3, but the diodes D1 and D2 in FIG. 3 are RC-IGBTs integrated with the transistors Q1 and Q2, that is, the transistors Q10 and Q20, respectively.

By adopting such a configuration, the power module 200 can improve assemblability as compared with a case where an upper surface electrode of a chip-shaped semiconductor element and a main wiring board are connected by ultrasonic welding. Furthermore, since it is not necessary to insert an instrument for bonding from an upper surface of a case, it is not necessary to provide an opening, and it is easy to reduce the size of the power module 200. Furthermore, even a change in the size of the semiconductor element to be mounted can be flexibly coped with by adjusting arrangement and heights of the wires MR, and productivity can be improved.

### Third Embodiment

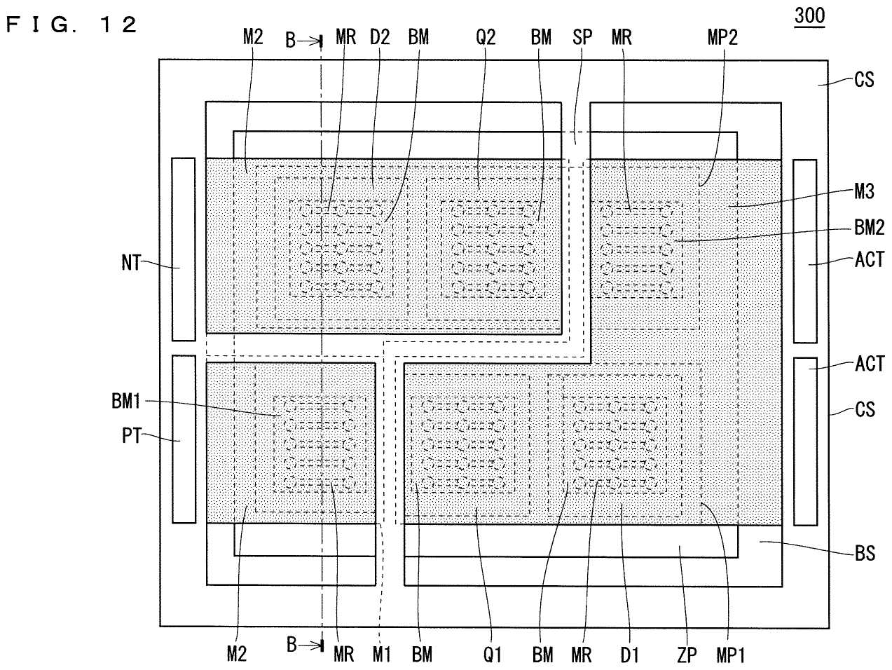

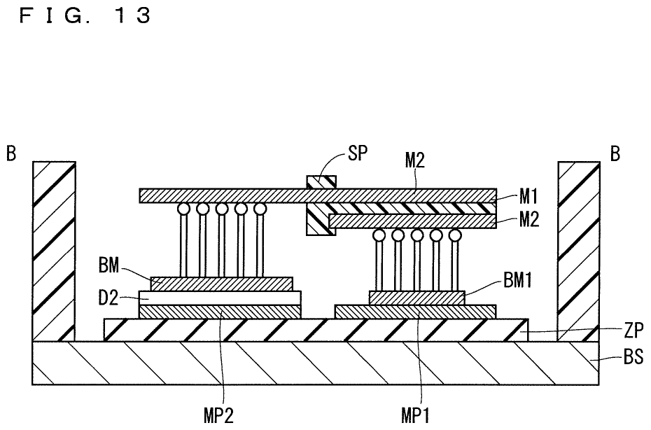

FIG. 12 is a plan view illustrating a configuration of a power module 300 according to Third Embodiment, and is a top view of the power module 300 as viewed from above. FIG. 13 is a cross-sectional view taken along line B-B of arrow directions in FIG. 12. Note that in FIGS. 12 and 13, identical elements to those of the power module 100 described with reference to FIGS. 1 and 2 are given identical reference signs, and repeated description is omitted.

In the power module 300 illustrated in FIGS. 12 and 13, the number and arrangement of transistors Q1 and Q2, diodes D1 and D2, and independent bonding materials BM1 and BM2 mounted on a base plate BS are identical to those of the power module 100 described with reference to FIGS. 1 and 2, but a main wiring board M2 has an L-shaped planar shape so as to cover an upper side of the transistor Q2 and the diode D2 and further cover an upper side of a main wiring board M1 that covers an upper side of the independent bonding material BM2 provided on a conductor pattern MP2.

That is, as illustrated in FIG. 13, the main wiring board M2, which is electrically connected to an upper surface electrode of the diode D2 on the conductor pattern MP2 by wires MR and the bonding material BM, extends to a position above the main wiring board M1. The main wiring board M1 and the main wiring board M2 above the main wiring board M1 face each other with the wiring support portion SP interposed therebetween, and form a parallel plate structure. Note that the main wiring board M1 and the main wiring board M2 are electrically insulated because the wiring support portion SP made of an insulating material is interposed between the main wiring board M1 and the main wiring board M2.

Furthermore, as illustrated in FIG. 13, the main wiring board M1 is electrically connected to the independent bonding material BM1 on a conductor pattern MP1 with the wires MR, but a planar shape of the main wiring board M1 is identical to that of the power module 100 of First Embodiment.

Furthermore, as illustrated in FIG. 12, a planar shape of the main wiring board M3 is also identical to that of the power module 100 of First Embodiment, and electrical connection between the main wiring board M3 and the transistor Q1, the diode D1, and the independent bonding material BM2 with the wires MR is also identical to that of the power module 100 of First Embodiment.

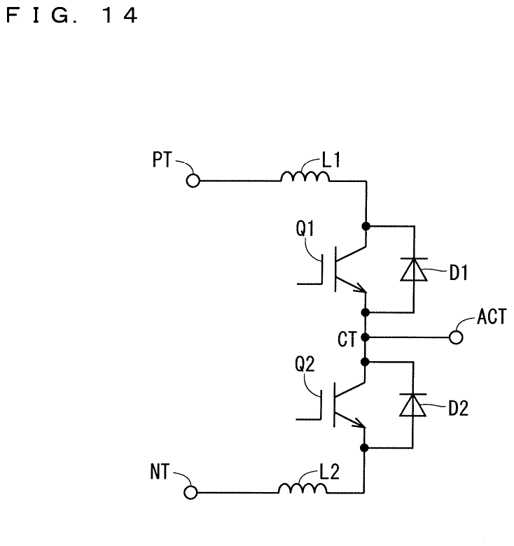

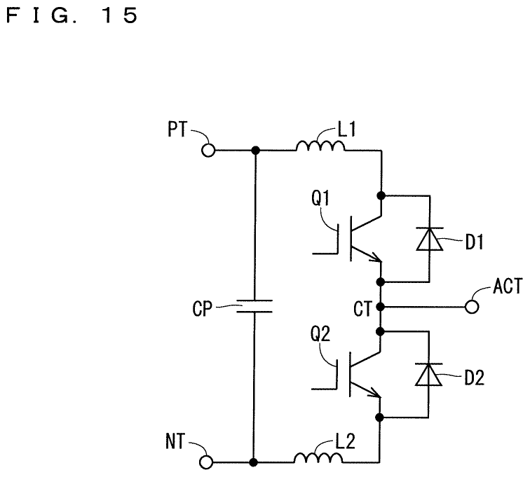

As described above, the main wiring board M1 and the main wiring board M2 above the main wiring board M1 have a parallel plate structure. The main wiring boards M1 and M2 are main wiring boards through which a main current flows, and by having the parallel plate structure, it is possible to reduce an induction component of a circuit through which the main current of the power module 300 flows, and it is possible to suppress occurrence of an oscillation phenomenon during switching operation of the power module 300. This mechanism will be described with reference to FIGS. 14 and 15.

FIG. 14 is a circuit diagram illustrating a single-phase inverter circuit in a case where the above-described parallel plate structure is not provided. FIG. 14 is a circuit diagram basically identical to the inverter circuit described with reference to FIG. 3 in First Embodiment, and identical elements to those of the inverter circuit in FIG. 3 are given identical reference signs, and repeated description is omitted.

As illustrated in FIG. 14, in a case where the parallel plate structure is not provided, inductance L1 exists in a conduction path between the P-side terminal PT and the transistor Q1 and the diode D1, and inductance L2 exists in a conduction path between the N-side terminal NT and the transistor Q2 and the diode D2, and therefore an oscillation phenomenon occurs during switching operation of the power module 300. However, in a case where the main wiring board M1 connected to the P-side terminal PT and the main wiring board M2 connected to the N-side terminal NT have the parallel plate structure, capacitance (capacitance component) CP is formed between the P-side main wiring and the N-side main wiring, as illustrated in FIG. 15. By providing the capacitance CP, the inductance component in the entire circuit is decreased, and as a result, occurrence of an oscillation phenomenon during the switching operation can be suppressed, and switching loss can be reduced.

### Modification

In Embodiments 1 to 3 described above, a semiconductor that constitutes a semiconductor element is not particularly limited, but the semiconductor is not limited to silicon (Si) regarding both of a transistor and a diode, and a wide band gap semiconductor such as silicon carbide (SiC) and gallium nitride (GaN) can be used. A semiconductor element made of a wide band gap semiconductor is excellent in withstand voltage, high in allowable current density, and high in heat resistance and thus can operate at a high temperature, as compared with a semiconductor element made of Si.

Although the present disclosure has been described in detail, the above description is illustrative in all aspects, and the present disclosure is not limited thereto. It is understood that numerous modifications not illustrated can be assumed without departing from the scope of the present disclosure.

The embodiments of the present disclosure can be freely combined and changed or omitted as appropriate within the scope of the present disclosure.

1. A power module comprising:
a plurality of semiconductor elements through which a main current flows in a thickness direction;
a substrate on which the plurality of semiconductor elements are mounted;
a base plate on which the substrate is mounted;
a case that is bonded to the base plate and houses the plurality of semiconductor elements;
a plurality of main wiring boards incorporated in an upper portion of the case on a side opposite to the base plate and arranged in parallel to the base plate; and
a plurality of wires bonded to lower surfaces of the plurality of main wiring boards that face the plurality of semiconductor elements,
wherein an upper surface electrode of each of the plurality of semiconductor elements is electrically connected to a corresponding one of the plurality of main wiring boards with the plurality of wires and a bonding material.

2. The power module according to claim 1, wherein
the plurality of main wiring boards and the plurality of wires are made of copper or a copper alloy, and
the bonding material is made of solder.

3. The power module according to claim 2, wherein both ends of each of the plurality of wires are bonded to a corresponding one of the plurality of main wiring boards so as to have a loop shape protruding from a lower surface of the corresponding one of the plurality of main wiring boards, and a tip of a loop is bonded to the upper surface electrode of a corresponding one of the plurality of semiconductor elements with a bonding material.

4. The power module according to claim 2, wherein
the case includes a case upper portion corresponding to the upper portion of the case and a case lower portion bonded to the base plate, and
each of the plurality of wires is bonded to the upper surface electrode of a corresponding one of the plurality of semiconductor elements with the bonding material in a state where the case upper portion is bonded to the case lower portion.

5. The power module according to claim 1, wherein
the plurality of main wiring boards include a first main wiring board, a second main wiring board, and a third main wiring board,
the plurality of semiconductor elements include a first switching element and a second switching element that are connected in series between the first main wiring board to which a first potential is applied and the second main wiring board to which a second potential lower than the first potential is applied and that operate in a complementary manner,
the third main wiring board is connected to a connection node between the first switching element and the second switching element, and
a parallel plate structure is provided in which a part of the second main wiring board covers the first main wiring board with an insulating material interposed therebetween.

6. The power module according to claim 1, wherein the plurality of semiconductor elements are a plurality of reverse-conducting transistors each including a free wheeling diode.
